(19) United States
(12) Patent Application Publication
(10) Pub. No.: US 2009/0072318 A1
(43) Pub. Date: Mar. 19, 2009

(54) Semiconductor Device and Method of Fabricating the Same

(76) Inventor: Hyung Sun Yun, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/212,053

(22) Filed: Sep. 17, 2008

(30) Foreign Application Priority Data
Sep. 19, 2007 (KR) 10-2007-0095328

(51) Int. Cl. H01L 29/78; H01L 21/336

(52) U.S. Cl. 257/366; 438/283; 257/E29.264; 257/E21.421

(57) ABSTRACT

Disclosed are a semiconductor device and a method of fabricating the same. The semiconductor device can include a gate insulating layer on a semiconductor substrate, a gate electrode on the gate insulating layer and source/drain regions in the semiconductor substrate at sides of the gate electrode. The gate electrode includes a first gate electrode and a second gate electrode on and electrically connected to the first gate electrode.

### CROSS-REFERENCE TO RELATED APPLICATION

The present application claims the benefit under 35 U.S.C. §119 to Korean Patent Application No. 10-2007-0095328, filed Sep. 19, 2007, which is hereby incorporated by reference in its entirety.

### BACKGROUND

In general, power devices can be classified into bipolar-based devices, MOSFET (metal oxide semiconductor field effect transistor)—based devices, and combination devices such as the IGBT (insulated gate bipolar transistor).

Traditionally, bipolar devices are used for power devices because of their capability to provide high current and high blocking voltage. However, with the improvements to MOS technology, MOSFET devices are becoming popular as power devices for lower voltage applications. For example, the MOSFET device has input impendence higher than that of a bipolar transistor, high power gain, and can operate at higher frequencies. Advantageously, a gate driving circuit of the MOSFET is very simple. In addition, since the MOSFET is a unipolar device, time delay caused by storage or recombination of minority carriers may not occur when the device is turned off.

However, communication devices require transistors including a gate electrode having low resistance.

### BRIEF SUMMARY

Embodiments of the present invention provide a high performance semiconductor device including a gate electrode having superior characteristics and a method of fabricating the same.

A semiconductor device according to an embodiment can include a well region on a semiconductor substrate, source/drain regions spaced apart from each other in the well region, a gate insulating layer on the semiconductor substrate on an area between the source/drain regions, a first gate electrode on the gate insulating layer, and a second gate electrode on the first gate electrode.

A method of fabricating a semiconductor device according to an embodiment can include forming a gate insulating layer on a well region of a semiconductor substrate, forming a first gate electrode on the gate insulating layer, forming source/drain regions in the well region beside the first gate electrode, and forming a second gate electrode on the first gate electrode.

The semiconductor device according to embodiments includes a gate electrode having a first gate electrode and a second gate electrode.

The first gate electrode can include a material having superior adhesive characteristic relative to the gate insulating layer, and the second gate electrode can include a material having low resistance. Thus, the characteristics of the gate electrode and performance of the semiconductor device can be improved. In addition, the semiconductor device can be driven at low voltage.

### BRIEF DESCRIPTION OF THE DRAWINGS

FIG. 1 is a cross-sectional view of a MOS transistor including a gate electrode having a dual layer structure according to an embodiment of the present invention

FIGS. 2a to 2e are cross-sectional views showing a process for fabricating a MOS transistor according to an embodiment of the present invention.

FIGS. 3a to 3e are cross-sectional views showing a process for fabricating a MOS transistor according to another embodiment of the present invention.

### DETAILED DESCRIPTION

Hereinafter, embodiments of a MOS transistor and methods for fabricating the same will be described with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

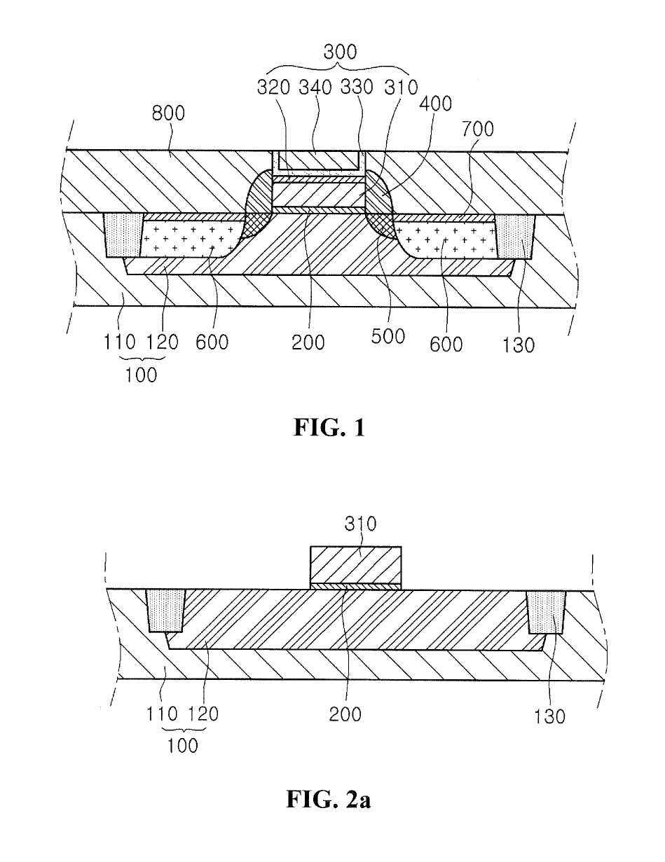

FIG. 1 is a cross-sectional view of a MOS transistor including a gate electrode having a dual layer structure according to an embodiment.

Referring to FIG. 1, a MOS transistor according to an embodiment can include a gate electrode 300 having multiple conductive portions. In a specific embodiment, a semiconductor device according to an embodiment can include a semiconductor substrate 100, an isolation layer 130, a gate insulating layer 200, a gate electrode 300, a gate spacer 400, an LDD region 500, source/drain regions 600, a second silicide layer 700, and an interlayer dielectric layer 800.

The semiconductor substrate 100 can include a first region 110 including N type impurities and a P well region 120 including P type impurities. In an embodiment, the semiconductor substrate 100 can be fabricated by using amorphous silicon.

The isolation layer 130 can be formed on the semiconductor substrate 100. The isolation layer 130 can be provided in a trench formed in the semiconductor substrate 100. In one embodiment, the isolation layer 130 can be fabricated by using oxide. The isolation layer 130 serves to isolate the MOS transistor.

The gate insulting layer 200 can be formed on the semiconductor substrate 100. The gate insulating layer 200 can be provided on the P well region 120. In an embodiment, the gate insulating layer 200 can be fabricated by using silicon dioxide (SiO₂).

The gate electrode 300 can be disposed on the gate insulating layer 200. The gate electrode 300 includes a first gate electrode 310, a first silicide layer 320, a conductive buffer layer 330 and a second gate electrode 340.

The first gate electrode 310 can be formed on the gate insulating layer 200. The first gate electrode 310 serves as a conductor. For example, the first gate electrode 310 can be fabricated by using polycrystalline silicon (polysilicon) or silicide.

The first silicide layer 320 can be formed on the first gate electrode 310. The first silicide layer 320 includes silicide. The first silicide layer 320 serves as a conductor and is electrically connected to the first gate electrode 310.

The buffer layer 330 can be formed on the first silicide layer 320. The buffer layer 330 also serves as a conductor and is electrically connected to the first silicide layer 320.

In certain embodiments, the buffer layer 330 can be fabricated by using, for example, Ti, TiN, TiSiN, Ta, TaN or TaSiN.

The buffer layer 330 can be interposed between the first silicide layer 320 and the second gate electrode 340 to improve bonding force between the first silicide layer and the second gate electrode 340.

In addition, the buffer layer 330 can be formed at a side of the second gate electrode 340 to inhibit materials in the interlayer dielectric layer 800 from diffusing into the second gate electrode 340 or vice versa.

The second gate electrode 340 can be formed on the buffer layer 330. The second gate electrode 340 serves as a conductor and is electrically connected to the buffer layer 330.

In certain embodiments, the second gate electrode 340 can be fabricated by using, for example, Ni, W, Al, or Cu.

The gate spacer 400 can be formed on a side of the first gate electrode 310. The gate spacer 400 insulates the side of the first gate insulating layer 310. For instance, the gate spacer 400 can be fabricated by using nitride.

In another embodiment, the gate spacer 400 can be formed on the sides of the first gate electrode 310 and the first silicide layer 320. Alternatively, the gate spacer 400 can be formed on the sides of both the first and second gate electrodes 310 and 340 to insulate the sides of the first and second gate electrodes 310 and 340.

The LDD region 500 can be formed under the gate spacer 400. The LDD region 500 can include lightly doped N type impurities.

The source/drain regions 600 can be aligned beside the gate electrode 300 on the P well region 120. Two source/drain regions 600 are spaced apart from each other. The two source/drain regions 600 face each other about the LDD region 500. The source/drain regions 600 can include heavily doped N type impurities.

The second silicide layer 700 can be formed on the source/drain regions 600. The second silicide layer 700 includes silicide and is electrically connected to the source/drain regions 600.

The interlayer dielectric layer 800 can be formed on the semiconductor substrate 100 while covering the lateral side of the gate electrode 300. The interlayer dielectric layer 800 exposes the top surface of the second gate electrode 340. In an embodiment, the interlayer dielectric layer 800 can be fabricated by using BPSG (boron phosphorus silicate glass) or USG (undoped silicate glass).

According to embodiments, the adhesive force of the first gate electrode 310 to the gate insulating layer 200 is greater than adhesive force of the first gate electrode 310 to the second gate electrode 340.

For instance, the gate insulating layer 200 can include silicon oxide, the first gate electrode 310 can include polysilicon, and the second gate electrode 340 can include metal.

In this case, the crystal structure of the first gate electrode 310 is similar to that of the gate insulating layer 200. In addition, both the first gate electrode 310 and the gate insulating layer 200 include silicon, so that adhesive force of the first gate electrode 310 to the gate insulating layer 200 is greater than adhesive force of the first gate electrode 310 to the second gate electrode 340.

In addition, if the first gate electrode 310 includes polysilicon, the amount of oxygen, which diffuses into the first gate electrode 310 from the gate insulating layer 200, is reduced as compared with a case in which the first gate electrode 310 includes metal. This is because oxidant effect of the silicon is lower than that of the metal.

Furthermore, the resistance of the second gate electrode 340 can be lower than that of the first gate electrode 310.

For example, if the second gate electrode 340 includes the metal and the first gate electrode 310 includes the polysilicon, resistance of the second gate electrode 340 is lower than that of the first gate electrode 310.

Therefore, the gate electrode 300 can be securely bonded to the gate insulating layer 200 due to the first gate electrode 310, and the resistance of the gate electrode 300 can be lowered due to the second gate electrode 340.

Accordingly, mechanical and electrical characteristics of the gate electrode 300 can be enhanced and performance of the MOS transistor can be improved. That is, the MOS transistor can be driven at low voltage with high response speed and operational speed. Thus, the MOS transistor can be applied to electric devices requiring the high speed operation.

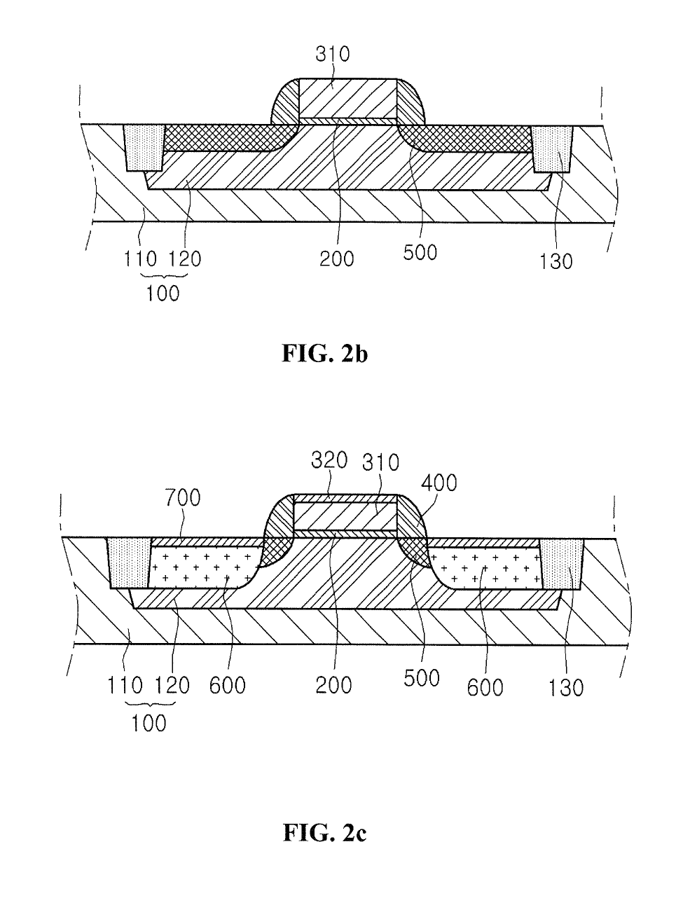

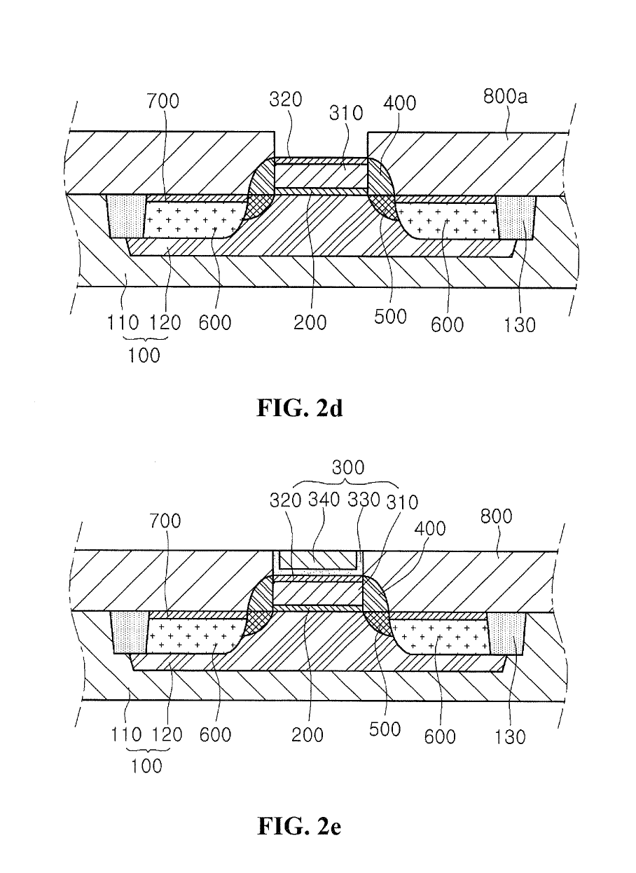

FIGS. 2a to 2e are cross-sectional views showing a process for fabricating a MOS transistor according to an embodiment.

Referring to FIG. 2a, an isolation layer 130 can be formed in a semiconductor substrate 100. According to an embodiment, the isolation layer 130 can be formed by forming a trench in a semiconductor substrate filling the trench with oxide. The isolation layer 130 can be formed in an N-type semiconductor substrate or a region doped with N-type impurities 110.

After the isolation layer 130 has been formed, P type impurities can be implanted into a region defined by the isolation layer 130 to form a P well region 120.

An oxide layer and a polysilicon layer can be sequentially formed on the semiconductor substrate 100. In certain embodiments, the oxide layer can be formed through a thermal oxidation process or a CVD (chemical vapor deposition) process.

Then, the oxide layer and the polysilicon layer can be patterned through a mask process to form a gate insulating layer 200 and a first gate electrode 310.

Referring to FIG. 2b, a lightly doped drain region (LDD) region 500 can be formed by implanting N type impurities at low concentration into the P well region 120 using the first gate electrode 310 as an ion implantation mask.

Then, a nitride layer can be formed on the entire surface of the semiconductor substrate 100 and etched through an anisotropic etching process, such as an etch back process to form a gate spacer 400 at the sides of the first gate electrode 310.

Referring to FIG. 2c, heavily doped source/drain regions 600 can be formed by implanting N type impurities into the P well region 120 using the first gate electrode 310 and the gate spacer 400 as an ion implantation mask.

Silicide can be formed on the source/drain regions 600 and the first gate electrode 310 by depositing a metal layer on the substrate including the source/drain regions 600 and the first gate electrode 310, performing an RTP (rapid temperature process), and removing un-reacted metal from the substrate. The metal layer can include, for example, Ni, Ti, Ta, or Pt.

The un-reacted metal of the metal layer can be removed by etchant. Accordingly, a first silicide layer 320 can be formed on the first gate electrode 310 and a second silicide layer 700 can be formed on the source/drain regions 600.

Referring to FIG. 2d, an insulating layer can be formed on the semiconductor substrate 100 and a trench can be formed in the insulating layer exposing the first silicide layer 320. The insulating layer with the trench can be referred to as a preliminary interlayer dielectric layer 800a. According to embodiments, the preliminary interlayer dielectric layer 800a can include BPSG or USG.

Referring to FIG. 2e, a preliminary buffer layer can be formed on the entire surface of the semiconductor substrate 100. In detail, the preliminary buffer layer can be formed on the preliminary interlayer dielectric layer 800a including in the trench. Accordingly, the preliminary buffer layer can be formed on the top surface of the first silicide layer 320 and on the side surfaces of the preliminary interlayer dielectric layer 800a in the trench.

In certain embodiments, the preliminary buffer layer can be formed by using Ti, TiN, TiSiN, Ta, TaN, or TaSiN.

After the preliminary buffer layer has been formed, a metal layer can be deposited to fill in the trench. The metal layer can include, for example, Ni, W, Al, or Cu. The metal layer can be deposited using any suitable method known in the art, including plating or a physical deposition method.

Then, the metal layer and the preliminary buffer layer can be etched through a CMP (chemical mechanical polishing) process. In one embodiment, the preliminary interlayer dielectric layer 800a can be used as an etch stop layer during the CMP process so that top surfaces of the metal layer, the preliminary buffer layer and the preliminary interlayer dielectric layer 800a are planarized and the metal layer and preliminary buffer layer remain only in the trench. Accordingly, the interlayer dielectric layer 800, the buffer layer 330 and the second gate electrode 340 can be formed.

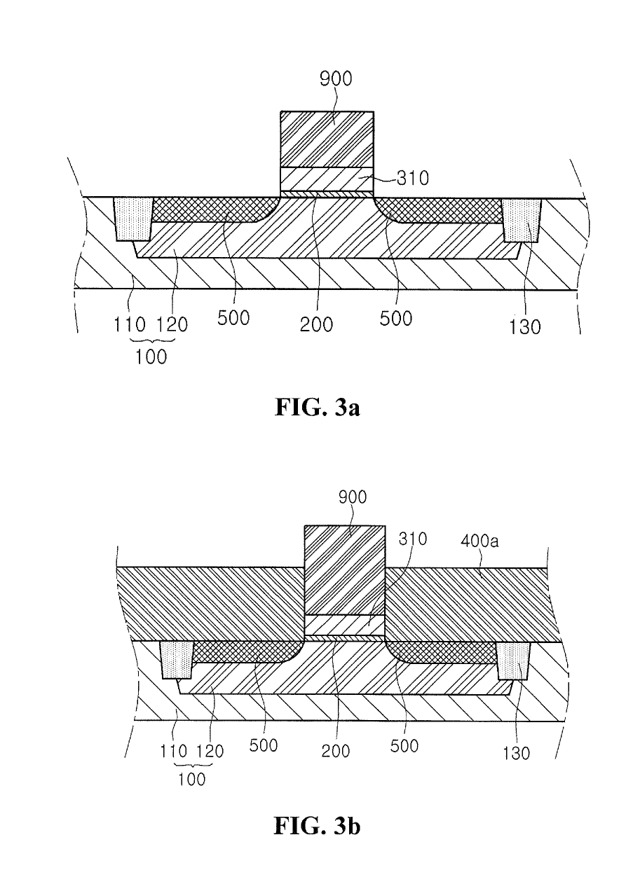

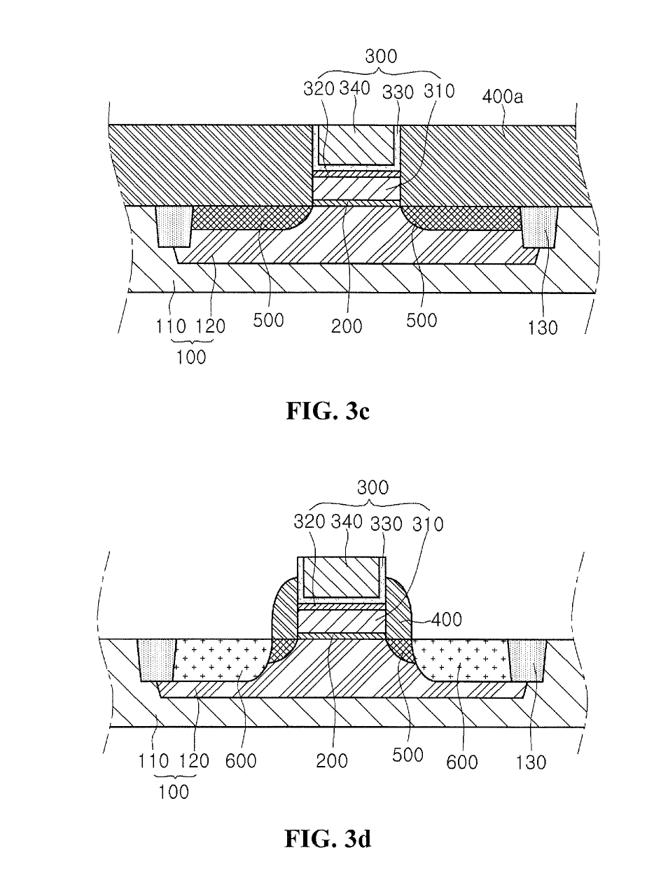

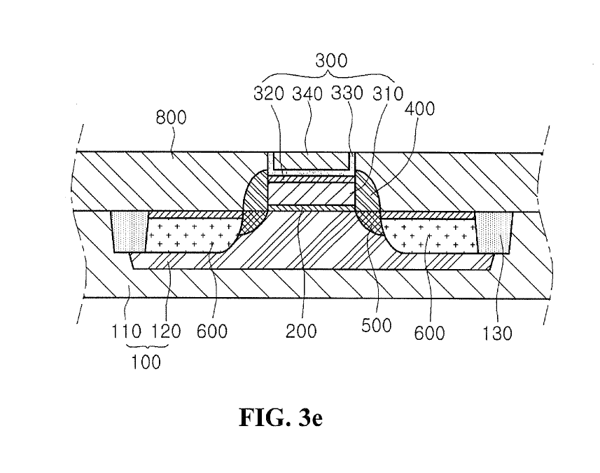

FIGS. 3a to 3e are cross-sectional views showing a process for fabricating a MOS transistor according to another embodiment.

Referring to FIG. 3a, an isolation layer 130 can be formed in a semiconductor substrate 100. According to one embodiment, the isolation layer 130 can be formed by forming a trench in a semiconductor substrate doped with N type impurities 110 and filling the trench with oxide.

Then, a P well region 120 can be formed in the N-type semiconductor substrate 110 by implanting P type impurities into a region of the substrate defined by the isolation layer 130.

An oxide layer can be formed on the semiconductor substrate 100 (having the N-type region 110 and the P well region 120) through a thermal oxidation process or a CVD (chemical vapor deposition) process. Then, a polysilicon layer can be formed on the oxide layer.

A photoresist pattern 900 can be formed on the polysilicon layer by coating the substrate with a photoresist film performing an exposure and development process.

The polysilicon layer and the oxide layer can be patterned by using the photoresist pattern 900 as an etch mask to form a gate insulating layer 200 and a first gate electrode 310.

Without removing the photoresist pattern 900, an LDD region 500 can be formed in the P well region 120 by implanting N type impurities at a low concentration using the photoresist pattern 900 as an ion implantation mask.

Referring to FIG. 3b, a nitride layer can be formed on the entire surface of the semiconductor substrate 100 including the photoresist pattern 900. The nitride layer can be partially etched through an isotropic etching process to form nitride layer 400a exposing an upper portion of the photoresist pattern 900.

Alternatively, the nitride layer can be etched through a CMP process until the top surface of the photoresist pattern 900 is exposed through the nitride layer 400a.

Referring to FIG. 3c, the photoresist pattern 900 can be removed through an etching process or an ashing process, exposing the first gate electrode 310.

Then, a first silicide layer 320 can be formed on the first gate electrode 310 by depositing a metal layer on the substrate including the nitride layer 400a and the first gate electrode 310, and performing an RTP. At this time, un-reacted metal of the metal layer can be removed.

After forming the first silicide layer 320, a preliminary buffer layer can be formed on the entire surface of the nitride layer 400a, an inner wall of the hole left by the removed photoresist pattern 900, and the top surface of the first silicide layer 320. According to an embodiment, the preliminary buffer layer can be formed by using, for example, Ti, TiN, TiSiN, Ta, TaN, or TaSiN.

Then, a metal layer can be formed on the preliminary buffer layer. The metal layer can include, for example, Ni, W, Al, or Cu,

The preliminary buffer layer, the metal layer and optionally the nitride layer 400a can be etched through a CMP process to form the buffer layer 330 and the second gate electrode 340.

Referring to FIG. 3d, after the second gate electrode 340 has been formed, the nitride layer can be etched through an anisotropic etching process, such as an etch back process to form a gate spacer 400 on the side surfaces of the first gate electrode 310 and the buffer layer 330.

Then, source/drain regions 600 can be formed by implanting N type impurities into a predetermined area of the P well region 120 using the second gate electrode 340 and the gate spacer 400 as an ion implantation mask.

Referring to FIG. 3e, a second silicide layer 700 can be formed by forming a metal layer on the source/drain regions 600 and performing an RTP. At this time, un-reacted metal of the metal layer can be removed by etchant.

After the second silicide layer 700 has been formed, an interlayer dielectric layer 800 can be formed on the entire surface of the semiconductor substrate 100. The interlayer dielectric layer 800 can be planarized through a CMP process to expose a top surface of the gate electrode 300. The interlayer dielectric layer 800 can include, for example, BPSG or USG.

Although not shown, interconnections can be formed through the interlayer dielectric layer 800 electrically connected to the second gate electrode 340 and the source/drain regions 600.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a gate insulating layer on a semiconductor substrate;
a gate electrode on the gate insulating layer, wherein the gate electrode comprises:
a first gate electrode on the gate insulating layer, and
a second gate electrode on the first gate electrode; and
source/drain regions in the semiconductor substrate at sides of the gate electrode.

2. The semiconductor device according to claim 1, wherein the gate electrode further comprises a conductive buffer layer disposed between the first gate electrode and the second gate electrode.

3. The semiconductor device according to claim 2, wherein the buffer layer comprises at least one selected from the group consisting of Ti, TiN, TiSiN, Ta, TaN, and TaSiN.

4. The semiconductor device according to claim 2, wherein the buffer layer is provided at side and bottom surfaces of the second gate electrode.

5. The semiconductor device according to claim 1, wherein the second gate electrode has resistance lower than resistance of the first gate electrode.

6. The semiconductor device according to claim 1, wherein adhesive force of the first gate electrode relative to the gate insulating layer is higher than adhesive force of the first gate electrode relative to the second gate electrode.

7. The semiconductor device according to claim 1, wherein the first gate electrode comprises polysilicon, and the second gate electrode comprises metal.

8. The semiconductor device according to claim 1, wherein the gate electrode further comprises a silicide layer disposed between the first and second gate electrodes and electrically connected to the first and second gate electrodes.

9. A method of fabricating a semiconductor device, the method comprising:
forming a gate insulating layer on a well region of a semiconductor substrate;
forming a first gate electrode on the gate insulating layer;
forming source/drain regions in the semiconductor substrate at sides of the first gate electrode; and
forming a second gate electrode on and electrically connected to the first gate electrode.

10. The method according to claim 9, further comprising forming an LDD region in the semiconductor substrate at sides of the first gate electrode after forming the first gate electrode and the gate insulating layer.

11. The method according to claim 9, wherein forming the second gate electrode comprises:
forming an insulating layer on the semiconductor substrate and forming a trench in the insulating layer exposing a top surface of the first gate electrode;
depositing a metal layer on the insulating layer including in the trench; and
etching the metal layer such that the metal layer remains only in the trench.

12. The method according to claim 11, further comprising forming spacers at sidewalls of the first gate electrode before forming the insulating layer, wherein the forming of the source/drain regions comprises implanting ions into the semiconductor substrate using the spacers and the first gate electrode as an ion implantation mask.

13. The method according to claim 12, further comprising forming a silicide layer on the first gate electrode and the source/drain regions before forming the insulating layer, wherein forming the trench in the insulating layer exposes the silicide layer on the first gate electrode.

14. The method according to claim 11, further comprising forming a conductive buffer layer on the insulating layer including on side and bottom surfaces of the trench before depositing the metal layer, and etching the buffer layer such that the conductive buffer layer remains only in the trench.

15. The method according to claim 14, wherein etching the conductive buffer layer and etching the metal layer comprises performing a chemical mechanical process with respect to the metal layer and the conductive buffer layer while using the insulating layer as an etch stop layer after forming the conductive buffer layer and depositing the metal layer.

16. The method as claimed in claim 9, wherein forming the second gate electrode comprises:
forming a hole forming layer on the first gate electrode;
forming an insulating layer on the semiconductor substrate and exposing at least a top surface of the hole forming layer;
removing the hole forming layer to expose a top surface of the first gate electrode
depositing a metal layer on the insulating layer including in the hole created by the removing of the hole forming layer; and
etching the metal layer such that the metal layer remains only in the hole.

17. The method according to claim 16, wherein the hole forming layer comprises a photoresist film having photosensitive characteristics.

18. The method according to claim 16, further comprising etching the insulating layer to form a gate spacer after etching the metal layer such that the metal layer remains only in the hole, wherein forming the source/drain regions comprises implanting ions into the semiconductor substrate using the gate spacer and the second gate electrode as an ion implantation mask.

19. The method according to claim 16, further comprising forming a silicide layer on the first gate electrode after removing the hole forming layer.

20. The method according to claim 16, further comprising forming a conductive buffer layer on the insulating layer including on side and bottom surfaces of the hole before depositing the metal layer, and etching the buffer layer such that the conductive buffer layer remains only in the hole.
